(19) United States
(12) Patent Application Publication
(10) Pub. No.: US 2022/0002184 A1
(43) Pub. Date: Jan. 6, 2022

(54) GLASS SUBSTRATES WITH MODIFIED SURFACE RESISTANT TO WEATHERING

(71) Applicant: Corning Incorporated, Corning, NY (US)

(72) Inventor: Nicholas James Smith, Port Matilda, PA (US)

(21) Appl. No.: 17/289,918

(22) PCT Filed: Oct. 17, 2019
(86) PCT No.: PCT/US2019/056649

§ 371 Date: Apr. 29, 2021

Related U.S. Application Data
(60) Provisional application No. 62/754,044, filed on Nov. 1, 2018.

(51) Int. Cl. C03C 3/093; C03C 3/083; C03C 3/085; C03C 3/087; C03C 3/091; C03C 23/00; H01L 33/60

(52) U.S. Cl. CPC C03C 3/093; C03C 3/083; C03C 3/085; H01L 33/60; C03C 3/091; C03C 23/009; C03C 3/087

(57) ABSTRACT

A light guide plate that includes a glass substrate including an edge surface and at least two major surfaces defining a thickness and an edge surface, the edge surface configured to receive light from a light source and the glass substrate configured to distribute the light from the light source, wherein the glass substrate comprises an alkali-containing bulk and an alkali-depleted surface layer, the alkali-depleted surface layer comprising about 0.5 atomic % alkali or less. Display products and methods of processing a glass substrate for use as a light guide plate are also provided.

### CROSS-REFERENCE TO RELATED APPLICATION

This application claims the benefit of priority under 35 U.S.C. § 119 of U.S. Provisional Application Ser. No. 62/754,044 filed on Nov. 1, 2018, the content of which is relied upon and incorporated herein by reference in its entirety.

### FIELD

The disclosure relates to a glass substrate comprising a modified surface which exhibits reduced weathering.

### BACKGROUND

Conventional components used to produce diffused light have included diffusive structures, including polymer light guides and diffusive films which have been employed in a number of applications in the display industry. These applications include bezel-free television systems, liquid crystal displays (LCDs), electrophoretic displays (EPD), organic light emitting diode displays (OLEDs), plasma display panels (PDPs), micro-electromechanical structures (MEMS) displays, electronic reader (e-reader) devices, and others.

Light guide plates (LGPs) are engineered components in display products such as televisions. With the natural transmission-based loss of light from the injection point via LEDs through the optical path length of the television, additional light extraction features (LEFs) are printed on one of the LGP surfaces (typically polymeric ink with dispersed SiO₂ or TiO₂ particles). These additional features facilitate extraction of light throughout the LGPs in edge-lit LED TV modules by inducing light scatter and breaking total internal reflection (TIR) within the LGP, causing light to be emitted at that point. These LEFs are typically patterned in a strategic manner such that they have a non-uniform distribution (based on, for example, the number of features per unit area, and/or the size of the features) proceeding across the LGP. Because the totally-internally-reflected light intensity is highest close to the LEDs (and diminishes in intensity as light is extracted, getting progressively dimmer proceeding further away from the LEDs), the non-uniform distribution of LEFs actually serves to compensate for the diminishing light intensity, and ultimately facilitates a uniform brightness of light extracted from the LGP towards the viewer. This is important to note because—if the LEFs were patterned uniformly across the LGP surface—it would lead to a very non-uniform (exponentially decaying) brightness distribution that is undesirable for the application. This is one problem introduced if uniformly-distributed, extraneous light-extraction features are present on the surface, as with so-called “weathering” products detailed herein.

Although plastic materials can provide adequate properties such as light transmission, these materials exhibit relatively poor mechanical properties such as rigidity, coefficient of thermal expansion (CTE) and moisture absorption. High-transmission glasses, such as the Iris' family of glasses commercially available from Corning Incorporated, have been employed as light guide plates (LGPs), which can replace polymer LGPs and provide superior mechanical properties. Indeed, such glass substrates can provide improved rigidity, lower coefficient of thermal expansion and reduced moisture absorption over poly(methyl methacrylate) (“PMMA”) and silyl-modified polyether (“MS”) counterparts.

When glass substrates are used as LGPs, it has been found that particulates can form on the glass surface upon accelerated aging under high humidity conditions (e.g., 60° C. and 90% RH), and will behave as extraneous light extraction features (LEFs). These particles, known to those skilled art as “weathering products,” create an inhomogeneous brightness profile over time across the panel. For example, when brightness is measured on a television panel that has been aged, compared to an unaged television panel, specific regions that contain weathering products exhibit increased brightness (measured in units of lumens or nits) in specific regions of the television panel. The effects of weathering products in some regions causes other regions on the same television panel to exhibit decreased brightness after weathering compared to an unaged television panel.

Weathering products cannot be feasibly removed after a display product containing the light guide plate has been assembled. Thus, weathering products can impact light transmission properties of the glass by scattering and light coupling through the glass panel due to additional light leakage. While it would be ideal if the luminance of the light guide plate did not change at all over the lifetime of the product due to weathering (i.e., the difference in brightness of an aged vs. unaged LGP would ideally be zero), in practice, LGPs can tolerate a certain level of luminance change within customer specifications (e.g., 80-90% brightness uniformity after accelerated aging tests). Nevertheless, it is possible under some condition for LGPs comprised of glass substrates to exceed these tolerances, particularly when they are maintained in high temperature and high humidity environments. The effect of weathering products (or in fact, any surface contamination) is also enhanced with the use of thinner LGPs.

Accordingly, there remains a need for glass substrates for use as a light guide plates that exhibit reduced effects from weathering, particularly when the glass substrate is exposed to high humidity environments.

### SUMMARY

One aspect of the disclosure provides a light guide plate that includes a glass substrate including an edge surface and at least two major surfaces defining a thickness and an edge surface configured to receive light from a light source and the glass substrate configured to distribute the light from the light source. The glass substrate includes an alkali-containing bulk; and an alkali-depleted surface layer, the alkali-depleted surface layer comprising about 0.5 atomic % alkali or less.

Another aspect of the disclosure provides a method of manufacturing a light guide plate, the method includes providing a glass substrate including at least two major surfaces defining a thickness and an edge surface configured to receive light from a light source and the glass substrate configured to distribute the light from the light source, contacting at least one of the at least two major surfaces with an electrode, subjecting the glass substrate to thermal poling, wherein weathering-based, non-uniformity in brightness in the light guide plate arising from formation of alkali products on the glass substrate is reduced, compared to a glass substrate that has not been subjected to thermal poling.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims. The accompanying drawings are included to provide a further understanding, and are incorporated in and constitute a part of this specification. The drawings illustrate one or more embodiment(s), and together with the description serve to explain principles and operation of the various embodiments.

### BRIEF DESCRIPTION OF THE. DRAWINGS

The following detailed description can be further understood when read in conjunction with the following drawings.

FIG. 1 is a cross-sectional view of an exemplary LCD display device;

FIG. 2 is a top view of an exemplary light guide plate;

FIG. 3 illustrates a light guide plate according to certain embodiments of the disclosure;

FIG. 4 depicts an anode/glass substrate/cathode assembly used in the Example;

FIG. 5 depicts optical microscope images of poled and unpoled regions of the anode-side surface of a glass substrate after humid aging at 85° C. and 85% humidity as described in the Example.

### DETAILED DESCRIPTION

In one or more embodiments, light guide plates comprising glass substrates are provided with an alkali-depleted surface layer. When used as a light guide plate, glass substrates with an alkali-depleted surface layer exhibit reduced weathering and less brightness non-uniformity in the light guide plate arising from formation of alkali products (e.g., sodium salts), compared to control glass substrates that have not been treated in accordance with the present disclosure (e.g., glass substrates that do not include an alkali-depleted surface layer). The reduced effects of such weathering can be determined by observing an effective reduction of particulate formation on treated glass substrates when the glass substrate is aged, for example, at 60° C. and at 90% relative humidity for 960 hours, or at 85° C. and at 85% relative humidity for 21 days, compared to an untreated substrate aged under the same conditions. The reduced effects of such weathering can be determined by luminance measurements. For example, a luminance increase, or reduction of the magnitude of a luminance increase, indicates a reduced effect of weathering for an aged substrate compared to an untreated substrate aged under the same conditions. In some embodiments, the aged substrate is aged at 60° C. and at 90% relative humidity for 960 hours or at 85° C. and at 85% relative humidity for 21 days. Other high temperature and/or high humidity environments can be applied to simulate (or accelerate) “aging” or “weathering” in high temperature and/or high humidity environments.

While the present disclosure is not limited to a particular theory, some glass substrates contain many single valence species, such as Na, at the glass surface. Alkali ions (e.g., Na⁺) within the surface layer can react with species in the air like carbon dioxide to form small white precipitates (e.g. sodium carbonate), generally less than a micrometer in size, and which can either nucleate or grow during the weathering process. It has been discovered that nucleation and growth is accelerated in a humid chamber (e.g., at 60° C. and 90% relative humidity for, e.g., 960 hours), and these precipitates (“weathering products”) have been detected as sodium carbonate and/or sodium chloride and result in an increase in luminance. While again not being bound by any particular theory, a glass substrate treated according to embodiments described herein results in an alkali-depleted surface layer, which reduces the formation of weathering products that would otherwise occur due to moisture-mediated out-diffusion of alkali ions over time.

As used herein according to one or more embodiments, “alkali-depleted” refers to a surface layer that has been treated in accordance with one or more embodiments comprises alkali in a concentration less than the concentration present in the alkali-containing bulk of the glass substrate that has not been treated. In some embodiments, the concentration of alkali in the alkali-depleted surface layer is about 0.5 atomic % or less (e.g., 0.001-0.5 atomic %). In such embodiments, in which the alkali concentration is about 0.5 atomic % or less (e.g., 0.001-0.5 atomic %), 0.4 atomic % or less (e.g., 0.001-0.4 atomic %), about 0.3 atomic % or less (e.g., 0.001-0.3 atomic %), about 0.2 atomic % or less (e.g., 0.001-0.2 atomic %), about 0.1 atomic % or less (e.g., 0.001-0.1 atomic %), or about 0.05 atomic % or less (e.g., 0.001-0.05 atomic %), the surface layer may be referred to as “alkali-free.” Presence of an alkali-depleted surface layer in a glass substrate and the thickness of an alkali-depleted surface layer can be measured by Secondary Ion Mass Spectroscopy (“SIMS”).

In one or more embodiments, the alkali-depleted surface layer is also an alkaline earth-depleted surface layer. As used herein, “alkaline earth-depleted” means the surface layer comprises alkaline earth in a concentration less than the concentration present in the alkali-containing bulk layer. In some embodiments, the concentration of alkaline earth in the alkali-depleted surface layer is about 0.5 atomic % or less (e.g., 0.001-0.5 atomic %). In such embodiments, in which the alkaline earth concentration is about 0.5 atomic % or less (e.g., 0.001-0.5 atomic %), about 0.4 atomic % or less (e.g., 0.001-0.4 atomic %), about 0.3 atomic % or less (e.g., 0.001-0.3 atomic %), about 0.2 atomic % or less (e.g., 0.001-0.2 atomic %), about 0.1 atomic % or less (e.g., 0.001-0.1 atomic %), or about 0.05 atomic % or less (e.g., 0.05-0.001 atomic %. Where the alkaline earth concentration is less than about 0.05 atomic % or less, the surface layer may be referred to as alkaline earth-free. Presence of an alkaline earth-depleted surface layer in a glass substrate and the thickness of an alkaline earth-depleted surface layer can be measured by Secondary Ion Mass Spectroscopy (“SIMS”).

In one or more embodiments, the alkali-depleted surface layer may have a thickness in the range from about 10 nm to about 5000 nm, from about 10 nm to about 4000 nm, from about 10 nm to about 3000 nm, from about 10 nm to about 2000 nm, from about 10 nm to about 1000 nm, from about 10 nm to about 900 nm, from about 10 nm to about 800 nm, from about 10 nm to about 700 nm, from about 10 nm to about 600 nm, from about 10 nm to about 500 nm, from about 50 nm to about 1000 nm, from about 100 nm to about 1000 nm, from about 200 nm to about 5000 nm, from about 250 nm to about 5000 nm, from about 300 nm to about 51000 nm, from about 400 nm to about 5000 nm, from about 500 nm to about 5000 nm, or from about 500 nm to about 5000 nm.

In one or more embodiments, the alkali-depleted surface layer has a substantially homogenous composition. In some embodiments, the composition of the alkali-depleted surface layer is substantially the same along the thickness of the surface layer. In other embodiments, the composition of the alkali-depleted surface layer is substantially the same along its entire volume. As used herein, the phrase “homogenous composition” refers to a composition that is not phase separated or does not include portions with a composition differing from other portions.

In one or more embodiments, the alkali-depleted surface layer may be substantially free of crystallites or is substantially amorphous. For example, in some embodiments, the alkali-depleted surface layer includes less than about 1 volume % crystallites.

In one or more embodiments, the alkali-depleted surface layer is substantially free of hydrogen, such as hydrogen in the form of H⁺, H₃O⁺, H₂O. In some embodiments, the alkali-depleted surface layer includes about 0.1 atomic % hydrogen or less (e.g., 0.001-0.1 atomic %), about 0.08 atomic % hydrogen or less (e.g., 0.001-0.08 atomic %), about 0.06 atomic % hydrogen or less (e.g., 0.001-0.06 atomic %), about 0.05 atomic % hydrogen or less (e.g., 0.001-0.05 atomic %), about 0.04 atomic % hydrogen or less (e.g., 0.001-0.04 atomic %), about 0.02 atomic % hydrogen or less (e.g., 0.001-0.02 atomic %), or about 0.01 atomic % hydrogen or less (e.g., 0.001-0.01 atomic %). The presence of hydrogen in a glass substrate can be measured by Secondary Ion Mass Spectroscopy (“SIMS”).

In one or more specific embodiments, the alkali-depleted surface layer comprises a binary Al₂O₃—SiO₂ composition, though other non-alkali components may be included.

The glass substrate comprises any material known in the art for use in display devices. In exemplary embodiments, the glass substrate comprises aluminosilicate, alkali-aluminosilicate, borosilicate, alkali-borosilicate, aluminoborosilicate, alkali-aluminoborosilicate, soda-lime, or other suitable glasses. In one embodiment, the glass is selected from an aluminosilicate glass, a borosilicate glass and a soda-lime glass. Examples of commercially available glasses suitable for use as a glass light guide plate include, but are not limited to, Iris™, and Gorilla® glasses from Corning Incorporated.

In one or more embodiments, the glass substrate comprises, in mol %, ranges of the following oxides: 50-90 mol % SiO₂, 0-20 mol % Al₂O₃, 0-20 mol % B₂O₃, and 0-25 mol % RₓO, wherein x is 2 and R is chosen from Li, Na, K, Rb, Cs, and combinations thereof, or wherein x is 1 and R is chosen from Zn, Mg, Ca, Sr, Ba, and combinations thereof, and wherein the glass substrate comprises 0.5-20 mol % of one oxide selected from Li₂O, Na₂O, K₂O, Rb₂O, Cs₂O and MgO. In one or more embodiments, the glass substrate comprises on a mol % oxide basis at least 3.5-20 mol %, 5-20 mol %, 10-20 mol % of one oxide selected from Li₂O, Na₂O, K₂O, Rb₂O, Cs₂O and MgO.

In one or more embodiments, the glass substrate comprises an aluminosilicate glass comprising at least one oxide selected from Li₂O, Na₂O, K₂O Rb₂O, Cs₂O and MgO, rendering the glass substrate susceptible to weathering products upon exposure to aging conditions described herein. In one or more embodiments, the glass substrate comprises, in mol %, ranges of the following oxides: SiO₂: from about 65 mol % to about 85 mol %; Al₂O₃: from about 0 mol % to about 13 mol %; B₂O₃: from about 0 mol % to about 12 mol %; Li₂O: from about 0 mol % to about 2 mol %; Na₂O: from about 0 mol % to about 14 mol %; K₂O: from about 0 mol % to about 12 mol %; ZnO: from about 0 mol % to about 4 mol %; MgO: from about 0 mol % to about 12 mol %; CaO: from about 0 mol % to about 5 mol %; SrO: from about 0 mol % to about 7 mol %; BaO: from about 0 mol % to about 5 mol %; and SnO₂: from about 0.01 mol % to about 1 mol %.

In one or more embodiments, the glass substrate comprises, in mol %, ranges of the following oxides: SiO₂: from about 70 mol % to about 85 mol %; Al₂O₃: from about 0 mol % to about 5 mol %; B₂O₃: from about 0 mol % to about 5 mol %; Li₂O: from about 0 mol % to about 2 mol %; Na₂O: from about 0 mol % to about 10 mol %; K₂O: from about 0 mol % to about 12 mol %; ZnO: from about 0 mol % to about 4 mol %; MgO: from about 3 mol % to about 12 mol %; CaO: from about 0 mol % to about 5 mol %; SrO: from about 0 mol % to about 3 mol %; BaO: from about 0 mol % to about 3 mol %; and SnO₂: from about 0.01 mol % to about 0.5 mol %.

In one or more embodiments, the glass substrate comprises, in mol %, ranges of the following oxides: SiO₂: from about 72 mol % to about 82 mol %; Al₂O₃: from about 0 mol % to about 4.8 mol %; B₂O₃: from about 0 mol % to about 2.8 mol %; Li₂O: from about 0 mol % to about 2 mol %; Na₂O: from about 0 mol % to about 9.3 mol %; K₂O: from about 0 mol % to about 10.6 mol %; ZnO: from about 0 mol % to about 2.9 mol %; MgO: from about 3.1 mol % to about 10.6 mol %; CaO: from about 0 mol % to about 4.8 mol %; SrO: from about 0 mol % to about 1.6 mol %; BaO: from about 0 mol % to about 3 mol %; and SnO₂: from about 0.01 mol % to about 0.15 mol %.

In one or more embodiments, the glass substrate comprises, in mol %, ranges of the following oxides: SiO₂: from about 80 mol % to about 85 mol %; Al₂O₃: from about 0 mol % to about 0.5 mol %; B₂O₃: from about 0 mol % to about 0.5 mol %; Li₂O: from about 0 mol % to about 2 mol %; Na₂O: from about 0 mol % to about 0.5 mol %; K₂O: from about 8 mol % to about 11 mol %; ZnO: from about 0.01 mol % to about 4 mol %; MgO: from about 6 mol % to about 10 mol %; CaO: from about 0 mol % to about 4.8 mol %; SrO: from about 0 mol % to about 0.5 mol %; BaO: from about 0 mol % to about 0.5 mol %; and SnO₂: from about 0.01 mol % to about 0.11 mol %.

In one or more embodiments, the glass substrate comprises, in mol %, ranges of the following oxides: SiO₂: from about 65.8 mol % to about 78.2 mol %; Al₂O₃: from about 2.9 mol % to about 12.1 mol %; B₂O₃: from about 0 mol % to about 11.2 mol %; Li₂O: from about 0 mol % to about 2 mol %; Na₂O: from about 3.5 mol % to about 13.3 mol %; K₂O: from about 0 mol % to about 4.8 mol %; ZnO: from about 0 mol % to about 3 mol %; MgO: from about 0 mol % to about 8.7 mol %; CaO: from about 0 mol % to about 4.2 mol %; SrO: from about 0 mol % to about 6.2 mol %; BaO: from about 0 mol % to about 4.3 mol %; and SnO₂: from about 0.07 mol % to about 0.11 mol %.

In one or more embodiments, the glass substrate comprises, in mol %, ranges of the following oxides: SiO₂: from about 66 mol % to about 78 mol %; Al₂O₃: from about 4 mol % to about 11 mol %; B₂O₃: from about 40 mol % to about 11 mol %; Li₂O: from about 0 mol % to about 2 mol %; Na₂O: from about 4 mol % to about 12 mol %; K₂O: from about 0 mol % to about 2 mol %; ZnO: from about 0 mol % to about 2 mol %; MgO: from about 0 mol % to about 5 mol %; CaO: from about 0 mol % to about 2 mol %; SrO: from about 0 mol % to about 5 mol %; BaO: from about 0 mol % to about 2 mol %; and SnO₂: from about 0.07 mol % to about 0.11 mol %.

In one or more embodiments, the glass substrate comprising the compositions provided herein has a color shift of less than 0.008 or less than 0.005. In one or more embodiments, the compositions provided herein are characterized by RₓO/Al₂O₃ being in a range of from 0.95 to 3.23, where x=2 and R is any one or more of Li, Na, K, Rb, and Cs. In one or more embodiments, R is any one of Zn, Mg, Ca, Sr or Ba, x=1 and RₓO/Al₂O₃ is in a range of from 0.95 to 3.23. In one or more embodiments, R is any one or more of Li, Na, K, Rb and Cs, x=2 and RₓO/Al₂O₃ is in a range of from 1.18 to 5.68. In one or more embodiments, R is any one or more of Zn, Mg, Ca, SR or Ba, x=1 and RₓO/Al₂O₃ is in a range of from 1.18 to 5.68. Suitable specific compositions for glass substrates according to one or more embodiments are described in International Publication Number WO2017/070066.

In one or more embodiments, glass substrates contain some alkali constituents, e.g., the glass substrates are not alkali-free glasses. As used herein, an “alkali-free glass” is a glass having a total alkali concentration which is less than or equal to 0.1 mole percent, where the total alkali concentration is the sum of the Na₂O, K₂O, and Li₂O concentrations. In some embodiments, the glass comprises Li₂O in the range of about 0 to about 3.0 mol %, in the range of about 0 to about 2.0 mol %, or in the range of about 0 to about 1.0 mol %, and all subranges therebetween. In other embodiments, the glass is substantially free of Li₂O. In other embodiments, the glass comprises Na₂O in the range of about 0 mol % to about 10 mol %, in the range of about 0 mol % to about 9.28 mol %, in the range of about 0 to about 5 mol %, in the range of about 0 to about 3 mol %, or in the range of about 0 to about 0.5 mol %, and all subranges therebetween. In other embodiments, the glass is substantially free of Na₂O. In some embodiments, the glass comprises K₂O in the range of about 0 to about 12.0 mol %, in the range of about 8 to about 11 mol %, in the range of about 0.58 to about 10.58 mol %, and all subranges therebetween.

The glass substrate can have any desired size and/or shape as appropriate to produce a desired light distribution. The glass substrate can comprise a second major surface opposite the surface that emits light. The major surfaces can, in certain embodiments, be planar or substantially planar, e.g., substantially flat. The first and second major surfaces can, in various embodiments, be parallel or substantially parallel. The glass substrate can include four edges, or may comprise more than four edges, e.g. a multi-sided polygon. In other embodiments, the glass substrate can comprise less than four edges, e.g., a triangle. By way of a non-limiting example, the light guide plate can comprise a rectangular, square, or rhomboid sheet having four edges, although other shapes and configurations can be employed.

In one or embodiments of the disclosure, the glass substrate such as a glass substrate can have a thickness of less than or equal to about 3 mm, for example, ranging from about 0.1 mm to about 3 mm, from about 0.1 mm to about 2.5 mm, from about 0.3 mm to about 2 mm, from about 0.5 mm to about 1.5 mm, or from about 0.7 mm to about 1 mm, including all ranges and subranges therebetween. The thermal poling process, discussed in greater detail below, is insensitive to glass thickness, provided that the glass substrate is sufficiently thick to avoid dielectric breakdown. In certain embodiments, the glass substrate has a thickness such that the poling voltage divided by thickness is greater than about 5×10⁷ V/m, or greater than 3×10⁸ V/m.

The glass substrate can be a high-transmission glass, such as a high-transmission aluminosilicate glass. In certain embodiments, the light guide plate exhibits a transmittance normal to the at least one major surface greater than 90% over a wavelength range from 400 nm to 700 nm. For instance, the light guide plate can have greater than about 91% transmittance normal to the at least one major surface, greater than about 92% transmittance normal to the at least one major surface, greater than about 93% transmittance normal to the at least one major surface, greater than about 94% transmittance normal to the at least one major surface, or greater than about 95% transmittance normal to the at least one major surface, over a wavelength range from 400 nm to 700 nm, including all ranges and subranges therebetween.

In certain embodiments, the edge surface of the glass substrate that is configured to receive light from a light source can scatter light within an angle less than 12.8 degrees full width half maximum (FWHM) in transmission. As disclosed in U.S. Published Application No. 2015/0368146, hereby incorporated by reference in its entirety, the edge surface configured to receive light from a light source can, in certain embodiments, be processed by grinding the edge without polishing, or by other methods for processing LGPs known to those or ordinary skill in the art.

The glass substrate can, in some embodiments, be chemically strengthened, e.g., by ion exchange. During the ion exchange process, ions within a glass at or near the surface of the glass can be exchanged for larger metal ions, for example, from a salt bath. The incorporation of the larger ions into the glass can strengthen the glass by creating a compressive stress in a near surface region. A corresponding tensile stress can be induced within a central region of the glass to balance the compressive stress.

According to various embodiments, the major surface of the glass substrate, after creation of the alkali-depleted surface layer, can be provided with one or more of a light extraction feature (LEF) or a lenticular lens applied over the surface layer. For example, a plurality of light extraction features can be present on or in the surface of the substrate in any given pattern or design, which may, for example, be random or arranged, repetitive or non-repetitive, uniform or non-uniform. In other embodiments, the light extraction features may be located within the matrix of the glass substrate adjacent the surface, or below the surface. For example, the light extraction features can be distributed across the surface, e.g., as textural features making up a roughened or raised surface, or may be distributed within and throughout the substrate or portions thereof, e.g., as laser-damaged features.

The LGP may be treated to create light extraction features according to any method known in the art, e.g., the methods disclosed in co-pending and co-owned International Patent Application Publication Nos. WO2014058748 and WO2015095288, each incorporated herein by reference in their entirety.

Embodiments of the disclosure provide a method of processing a glass substrate, for example, a glass substrate configured for use in a display device, and in some embodiments, a glass substrate configured to be used as a light guide plate. In certain embodiments, the alkali-depleted surface layer is formed by thermal poling.

Prior to thermal poling treatment, the surface of the glass substrate (and thus the surface layer) can be cleaned or treated to remove typical contamination that may accumulate after forming, storage and shipping. Alternatively, the glass substrate is subjected to treatment immediately after forming to eliminate the accumulation of contamination.

In one or more embodiments, the electrodes used in thermal poling comprise an anode in contact with an anodic surface of the glass substrate and a cathode in contact with a cathodic surface of the glass substrate. In certain embodiments, the anodic surface is subjected to positive DC bias while the cathodic surface is subject to negative DC bias.

In one or more embodiments, the electrode material is substantially more conductive than the glass at the poling temperature to provide for field uniformity over the modified surface area. It is also desirable that the anodic electrode material be relatively oxidation resistant to minimize the formation of an interfacial oxide compound that could cause sticking of the glass to the template. Exemplary anodic electrode materials include, but are not limited to, noble metals (e.g., Au, Pt, Pd, etc.) or oxidation-resistant, conductive films (e.g. TiN, TiAlN, graphitic coatings).

The cathodic electrode material according to some embodiments is conductive to likewise provide for field uniformity over the modified area. Exemplary materials for the cathodic electrode material include materials that can accept alkali ions from the glass, such as a graphite sheet (e.g., Grafoil® available from Graftech Inc.). In some embodiments, a physical cathodic electrode may not always be necessary to be brought into contact, due to surface discharge.

In one or more embodiments, the electrode(s) are separate components that are brought into contact with the glass, and thus can be separated after processing without complex removal steps. Electrodes can generally comprise a bulk material, or take the form of a thin film, for example, a conductive thin film that is deposited on the glass to serve as an electrode.

In some embodiments, the electrode covers all or only part of the surface, and may be intermittent or patterned as desired. Patterning can be achieved by any of a variety of methods, such as lithographic techniques, mechanical machining, or otherwise.

The curvature and/or flatness of the glass and the electrode should be ideally matched to provide for reasonably intimate contact at the interface over the affected area. However, even if initial contact is not intimate, the electrostatic charge at the interface when voltage is applied will act to pull the two surfaces into intimate contact.

Thermal poling, in certain embodiments, includes applying voltage to the glass substrate such that the anode is positively-biased relative to the glass substrate to induce alkali depletion at the anodic surface of the glass substrate. The voltage can be DC voltage or DC-biased AC voltage. Prior to applying the voltage, the method can include bringing the glass substrate and electrode (i.e., the stack including an anode/glass/cathode) to a temperature below Tg prior to applying voltage to the glass substrate. In some embodiments, the glass substrate and electrode can be brought to a process temperature in the range from about 25° C. up to about Tg, or from about 100° C. to about 300° C. In some embodiments, equilibrium at the desired process temperature during thermal poling ensures temperature uniformity across the poled surface of the glass substrate.

In one or more embodiments, the thermal poling treatment includes applying voltage in the range from about 100 volts to about 10,000 volts (e.g., from about 100 volts to about 1000 volts) to the glass substrate for a duration in the range from about 1 minute to about 6 hours (e.g., from about 5 minutes to about 60 minutes, from about 15 minutes to about 30 minutes). It should be noted that thermal poling treatment times and voltages can vary depending on glass composition. In some embodiments, the glass substrate is subjected to thermal poling under vacuum, in an inert gas environment (e.g., dry N₂), or a permeable gas environment (e.g., He).

Voltage can be applied in either one or more discrete steps to achieve a maximum desired value, or ramped (or increased) in a controlled/current-limited manner up to the process voltage. The voltage is applied in a manner to prevent thermal dielectric breakdown with the passage of too much current through the glass, such as low-resistivity glasses, allowing for higher final poling voltages and thicker surface layers. Alternatively, as breakdown strength varies with glass composition, surface condition, and ambient temperature, an “instant-on” strategy for applying voltage can also be tolerated under some conditions, and could be desired for convenience.

After thermal poling treatment, the glass substrate is cooled to a temperature in a range of from about 25° C. to about 80° C. for subsequent handling. The voltage can be removed prior to cooling or after cooling.

In one or more embodiments, apparatus suitable for performing poling treatments can include any system that can simultaneously maintain heat and voltage to the glass/electrode stack in a controlled manner while avoiding practical problems such as leakage current paths or arcing. In one or more embodiments, the apparatus also provides control of the process atmosphere (e.g., under vacuum, in an inert gas environment such as dry N₂, or permeable gas environment) which can minimize atmosphere effects and/or occluded gas at the interface.

Various devices comprising such light guides are also disclosed herein, such as display, lighting, and electronic devices, e.g., televisions, computers, phones, tablets, and other display panels, luminaires, solid-state lighting, billboards, and other architectural elements, to name a few.

Various embodiments of the disclosure will now be discussed with reference to the figures, which illustrate exemplary embodiments of microstructure arrays and light guide plates. The following general description is intended to provide an overview of the claimed devices, and various aspects will be more specifically discussed throughout the disclosure with reference to the non-limiting depicted embodiments, these embodiments being interchangeable with one another within the context of the disclosure.

An exemplary LCD display device 10 is shown in FIG. 1 comprising an LCD display panel 12 formed from a first substrate 14 and a second substrate 16 joined by an adhesive material 18 positioned between and around a peripheral edge portion of the first and second substrates. First and second substrates 14, 16 and adhesive material 18 form a gap 20 therebetween containing liquid crystal material. Spacers (not shown) may also be used at various locations within the gap to maintain consistent spacing of the gap. First substrate 14 may include color filter material. Accordingly, first substrate 14 may be referred to as the color filter substrate. On the other hand, second substrate 16 includes thin film transistors (TFTs) for controlling the polarization state of the liquid crystal material, and may be referred to as the backplane. LCD panel 12 may further include one or more polarizing filters 22 positioned on a surface thereof.

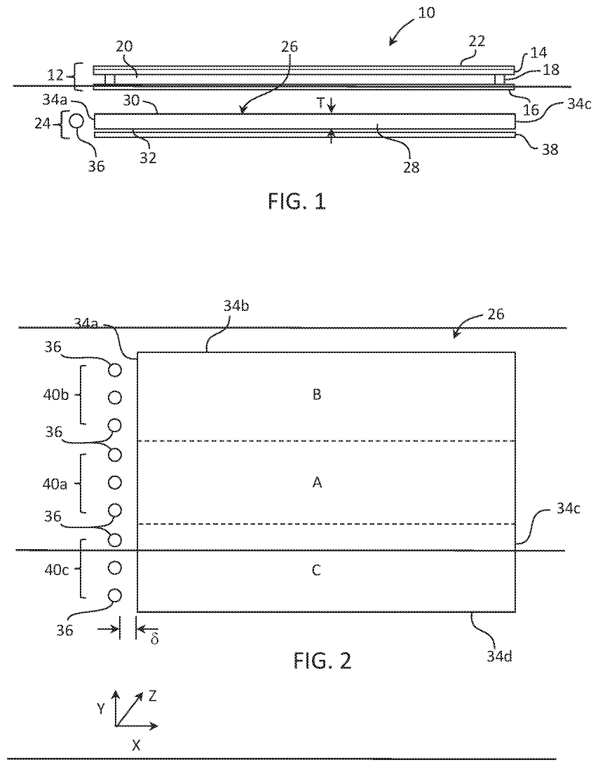

LCD display device 10 further comprises BLU 24 arranged to illuminate LCD panel 12 from behind, i.e., from the backplane side of the LCD panel. In some embodiments, the BLU may be spaced apart from the LCD panel, although in further embodiments, the BLU may be in contact with or coupled to the LCD panel, such as with a transparent adhesive. BLU 24 comprises a glass light guide plate (LGP) 26 formed with a glass substrate 28 as the light guide, glass substrate 28 including a first major surface 30, a second major surface 32, and a plurality of edge surfaces extending between the first and second major surfaces. In embodiments, glass substrate 28 may be a parallelogram, for example a square or rectangle comprising four edge surfaces 34a, 34b, 34c and 34d as shown in FIG. 2 extending between the first and second major surfaces defining an X-Y plane of the glass substrate 28, as shown by the X-Y-Z coordinates. For example, edge surface 34a may be opposite edge surface 34c, and edge surface 34b may be positioned opposite edge surface 34d. Edge surface 34a may be parallel with opposing edge surface 34c, and edge surface 34b may be parallel with opposing edge surface 34d. Edge surfaces 34a and 34c may be orthogonal to edge surfaces 34b and 34d. The edge surfaces 34a-34d may be planar and orthogonal to, or substantially orthogonal (e.g., 90+/−1 degree, for example 90+/−0.1 degree) to major surfaces 30, 32, although in further embodiments, the edge surfaces may include chamfers, for example a planar center portion orthogonal to, or substantially orthogonal to major surfaces 30, 32 and joined to the first and second major surfaces by two adjacent angled surface portions.

First and/or second major surfaces 30, 32 may include an average roughness (Ra) in a range from about 0.1 nanometer (nm) to about 0.6 nm, for example less than about 0.6 nm, less than about 0.5 nm, less than about 0.4 nm, less than about 0.3 nm, less than about 0.2 nm, or less than about 0.1 nm. An average roughness (Ra) of the edge surfaces may be equal to or less than about 0.05 micrometers (μm), for example in a range from about 0.005 micrometers to about 0.05 micrometers.

The foregoing level of major surface roughness can be achieved, for example, by using a fusion draw process or a float glass process followed by polishing. Surface roughness may be measured, for example, by atomic force microscopy, white light interferometry with a commercial system such as those manufactured by Zygo, or by laser confocal microscopy with a commercial system such as those provided by Keyence. The scattering from the surface may be measured by preparing a range of samples identical except for the surface roughness, and then measuring the internal transmittance of each. The difference in internal transmission between samples is attributable to the scattering loss induced by the roughened surface. Edge roughness can be achieved by grinding and/or polishing.

Glass substrate 28 further comprises a maximum glass substrate thickness t in a direction orthogonal to first major surface 30 and second major surface 32. In some embodiments, glass substrate thickness t may be equal to or less than about 3 mm, for example equal to or less than about 2 mm, or equal to or less than about 1 mm, although in further embodiments, glass substrate thickness t may be in a range from about 0.1 mm to about 3 mm, for example in a range from about 0.1 mm to about 2.5 mm, in a range from about 0.3 mm to about 2.1 mm, in a range from about 0.5 mm to about 2.1 mm, in a range from about 0.6 mm to about 2.1 mm, or in a range from about 0.6 mm to about 1.1 mm, including all ranges and subranges therebetween. In some embodiments, thickness of the glass substrate can be in the range from about 0.1 mm to about 3.0 mm (e.g., from about 0.3 mm to about 3 mm, from about 0.4 mm to about 3 mm, from about 0.5 mm to about 3 mm, from about 0.55 mm to about 3 mm, from about 0.7 mm to about 3 mm, from about 1 mm to about 3 mm, from about 0.1 mm to about 2 mm, from about 0.1 mm to about 1.5 mm, from about 0.1 mm to about 1 mm, from about 0.1 mm to about 0.7 mm, from about 0.1 mm to about 0.55 mm, from about 0.1 mm to about 0.5 mm, from about 0.1 mm to about 0.4 mm, from about 0.3 mm to about 0.7 mm, or from about 0.3 mm to about 0.55 mm).

In accordance with embodiments described herein, BLU 24 further comprises an array of light emitting diodes (LEDs) 36 arranged along at least one edge surface (a light injection edge surface) of glass substrate 28, for example edge surface 34a. It should be noted that while the embodiment depicted in FIG. 1 shows a single edge surface 34a injected with light, the claimed subject matter should not be so limited, as any one or several of the edges of an exemplary glass substrate 28 can be injected with light. For example, in some embodiments, the edge surface 34a and its opposing edge surface 34c can both be injected with light. Additional embodiments may inject light at edge surface 34b and its opposing edge surface 34d rather than, or in addition to, the edge surface 34a and/or its opposing edge surface 34c. The light injection surface(s) may be configured to scatter light within an angle less than 12.8 degrees full width half maximum (FWHM) in transmission.

In some embodiments, LEDs 36 may be located a distance δ from the light injection edge surface, e.g., edge surface 34a, of less than about 0.5 mm. According to one or more embodiments, LEDs 36 may comprise a thickness or height that is less than or equal to thickness t of glass substrate 28 to provide efficient light coupling into the glass substrate.

Light emitted by the array of LEDs is injected through the at least one edge surface 34a and guided through the glass substrate by total internal reflection, and extracted to illuminate LCD panel 12, for example by extraction features on one or both major surfaces 30, 32 of glass substrate 28. Such extraction features disrupt the total internal reflection, and cause light propagating within glass substrate 28 to be directed out of the glass substrate through one or both of major surfaces 30, 32. Accordingly, BLU 24 may further include a reflector plate 38 positioned behind glass substrate 28, opposite LCD panel 12, to redirect light extracted from the back side of the glass substrate, e.g., major surface 32, to a forward direction (toward LCD panel 12). Suitable light extraction features can include a roughed surface on the glass substrate, produced either by roughening a surface of the glass substrate directly, or by coating the sheet with a suitable coating, for example a diffusion film. Light extraction features in some embodiments can be obtained, for example, by printing reflective discrete regions (e.g., white dots) with a suitable ink, such as a UV-curable ink and drying and/or curing the ink. In some embodiments, combinations of the foregoing extraction features may be used, or other extraction features as are known in the art may be employed. BLU may further include one or more films or coatings (not shown) deposited on a major surface of the glass substrate, for example a quantum dot film, a diffusing film, and reflective polarizing film, or a combination thereof.

Local dimming, e.g., one dimensional (1D) dimming, can be accomplished by turning on selected LEDs 36 illuminating a first region along the at least one edge surface 34a of glass substrate 28, while other LEDs 36 illuminating adjacent regions are turned off. Conversely, 1D local dimming can be accomplished by turning off selected LEDs illuminating the first region, while LEDs illuminating adjacent regions are turned on.

FIG. 2 shows a portion of an exemplary LGP 26 comprising a first sub-array 40a of LEDs arranged along edge surface 34a of glass substrate 28, a second sub-array 40b of LEDs arranged along edge surface 34a of glass substrate 28, and a third sub-array 40c of LEDs 36 arranged along edge surface 34a of glass substrate 28. Three distinct regions of the glass substrate illuminated by the three sub-arrays are labeled A, B and C, wherein the A region is the middle region, and the B and C regions are adjacent the A region. Regions A, B and C are illuminated by LED sub-arrays 40a, 40b and 40c, respectively. With the LEDs of sub-array 40a in the “on” state and all other LEDs of other sub-arrays, for example the sub-arrays 40b and 40c, in the “off” state, a local dimming index LDI can be defined as 1−(average luminosity of the B, C regions)/(luminosity of the A region). A fuller explanation of determining LDI can be found, for example, in “Local Dimming Design and Optimization for Edge-Type LED Backlight Unit”: Jung, et al., SID 2011 Digest, 2011, pp. 1430-1432, the content of which is incorporated herein by reference in its entirety.

It should be noted that the number of LEDs within any one array or sub-array, or even the number of sub-arrays, is at least a function of the size of the display device, and that the number of LEDs depicted in FIG. 2 are for illustration only and not intended as limiting. Accordingly, each sub-array can include a single LED, or more than one LED, or a plurality of sub-arrays can be provided in a number as necessary to illuminate a particular LCD panel, such as three sub-arrays, four sub-arrays, five sub-arrays, and so forth. For example, a typical 1D local dimming-capable 55″ (139.7 cm) LCD TV may have 8 to 12 zones. The zone width is typically in a range from about 100 mm to about 150 mm, although in some embodiments the zone width can be smaller. The zone length is about the same as a length of glass substrate 28.

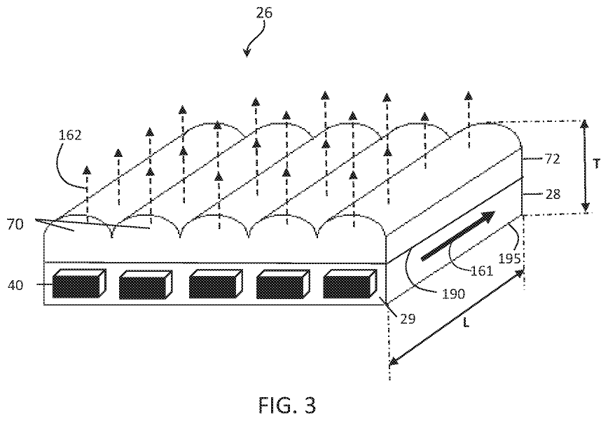

Referring now to FIG. 3, a light guide plate 26 is shown including at least one light source 40 that can be optically coupled to an edge surface 29 of the glass substrate 28, e.g., positioned adjacent to the edge surface 29. As used herein, the term “optically coupled” is intended to denote that a light source is positioned at an edge of the LGP so as to introduce light into the LGP. A light source may be optically coupled to the LGP even though it is not in physical contact with the LGP. Additional light sources (not illustrated) may also be optically coupled to other edge surfaces of the LGP, such as adjacent or opposing edge surfaces.

Light injected into the LGP from a light source 40 may propagate along a length L of the LGP as indicated by arrow 161 due to total internal reflection (TIR), until it strikes an interface at an angle of incidence that is less than the critical angle. TIR is the phenomenon by which light propagating in a first material (e.g., glass, plastic, etc.) comprising a first refractive index can be totally reflected at the interface with a second material (e.g., air, etc.) comprising a second refractive index lower than the first refractive index. TIR can be explained using Snell's law:

n₁ sin(θᵢ)=n₂ sin(θᵣ), (1)

which describes the refraction of light at an interface between two materials of differing indices of refraction. In accordance with Snell's law, n₁ is the refractive index of a first material, n₂ is the refractive index of a second material, θᵢ is the angle of the light incident at the interface relative to a normal to the interface (incident angle), and θᵣ is the angle of refraction of the refracted light relative to the normal. When the angle of refraction (θᵣ) is 90°, e.g., sin(θᵣ)=1, Snell's law can be expressed as:

$${θ}_{c} = {θ}_{i} = {sin}^{- 1} ( \frac{{n}_{2}}{{n}_{1}} ) \qquad ( 2 )$$

The incident angle θᵢ under these conditions may also be referred to as the critical angle θ_{c}. Light having an incident angle greater than the critical angle (θᵢ>θ_{c}) will be totally internally reflected within the first material, whereas light with an incident angle equal to or less than the critical angle (θᵢ≤θ_{c}) will be mostly transmitted by the first material.

In the case of an exemplary interface between air (n₁=1) and glass (n₂=1.5), the critical angle (θ_{c}) can be calculated as 41°. Thus, if light propagating in the glass strikes the air-glass interface at an incident angle greater than 41°, all the incident light will be reflected from the interface at an angle equal to the incident angle. If the reflected light encounters a second interface comprising an identical refractive index relationship as the first interface, the light incident on the second interface will again be reflected at a reflection angle equal to the incident angle.

In some embodiments, a polymeric platform 72 may be disposed on a major surface of the glass substrate 28, such as light emitting surface 190, opposite second major surface 195. The array of microstructures 70 may, along with other optical films (e.g., a reflector film and one or more diffuser films, not shown) disposed on surfaces 190 and 195 of the LGP, direct the transmission of light in a forward direction (e.g., toward a user), as indicated by the dashed arrows 162. In some embodiments, light source 40 may be a Lambertian light source, such as a light emitting diode (LED). Light from the LEDs may spread quickly within the LGP, which can make it challenging to effect local dimming (e.g., by turning off one or more LEDs). However, by providing one or more microstructures on a surface of the LGP that are elongated in the direction of light propagation (as indicated by the arrow 161 in FIG. 3), it may be possible to limit the spreading of light such that each LED source effectively illuminates only a narrow strip of the LGP. The illuminated strip may extend, for example, from the point of origin at the LED to a similar end point on the opposing edge. As such, using various microstructure configurations, it may be possible to effect one dimensional (1D) local dimming of at least a portion of the LGP in a relatively efficient manner.

### EXAMPLES

Various embodiments will be further clarified by the following non-limiting Example.

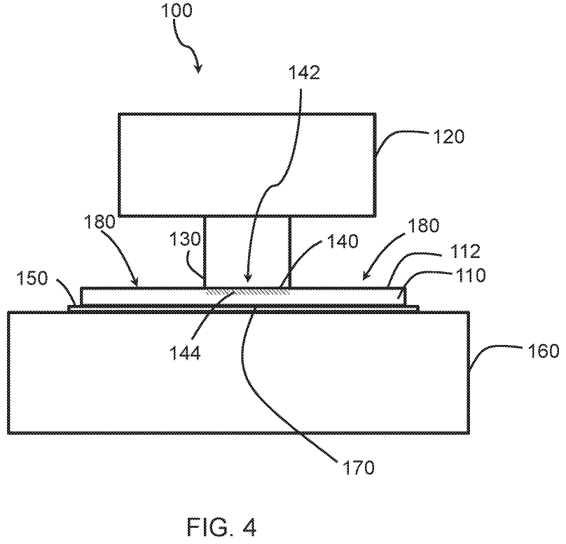

FIG. 4 depicts an anode/glass substrate/cathode stack or assembly 100 that is used in this Example for thermal poling of a glass substrate 110. The glass substrate is this Example had a composition as generally disclosed in WO2017/070066, hereby incorporated by reference in its entirety.

As shown in FIG. 4, a stainless steel metal electrode 120 in contact with a stainless steel gage block 130 acts as the anode, and contacts a major surface 112 of the glass substrate 110 to provide the anodic surface 140 of glass substrate 110. The gage block 130 has a flatness and surface area for intimate contact with the anodic surface 140. A piece of graphite 150 (Grafoil®), sitting on a stainless steel base plate 160 acts as the cathode, and contacts the opposing side of the glass substrate to form the cathodic surface 170 of the glass substrate. The surface area where the gage block 130 contacts the glass substrate 110 along the anodic surface 140 defines the poled region 142, whereas the surface portion of glass substrate not in contact with the gage block defines an unpoled regions 180 that serve as same-sample controls in this Example. The alkali-depleted surface layer is formed along this anodic surface 140, but not in the unpoled regions 180. The assembly 100 is wired appropriately to hold voltage inside a furnace.

After loosely stacking, a dry nitrogen atmosphere was created and the assembly (100) was heated to 250° C. After equilibrating at this temperature for 15 minutes, +600V was applied to the gage block 130, with current limited to 1 mA maximum. An initial increase in current was observed, followed by a slow decay as the alkali-depleted surface layer 144 is formed. The voltage was applied for a period of about 15 minutes, after which the heater was shut off and sample was allowed to cool overnight. The voltage was turned off, the chamber vented, and the stack was manually separated.

The glass substrate 110 was separated from the gage block manually and easily. The poled glass region was visually inspected and found to be clear and free of significant defects. In the poled region, a slight change in optical reflectance could be visually discerned, which can be taken as direct evidence for the presence of a low-index alkali-depleted surface layer in the range of a few hundred nm (i.e., a slight anti-reflective effect is created by the presence of the surface layer) The poled glass sample was put in a humidity chamber and treated for 21 days at 85° C. and 85% RH. These are considered extremely aggressive conditions for weathering. Past experiments have confirmed that an increase in illuminance occurs when an untreated glass substrate of the composition used in the Example is used in a light guide plate and aged under similar high temperature/high humidity conditions. The glass substrate 110 shown in FIG. 4 comprising the alkali-depleted surface layer 144 can be used as the light guide plates shown in FIGS. 1-3 and as part of the display device shown in FIG. 1. The glass substrate comprising the alkali-depleted surface layer exhibits reduced weathering compared with a glass substrate that does not include an alkali-depleted surface layer in accordance with one or more embodiments described herein.

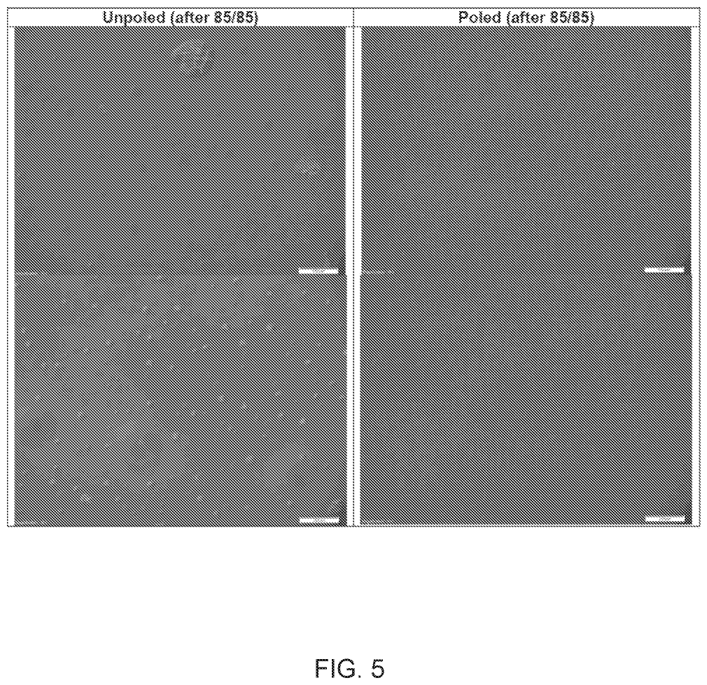

FIG. 5 depicts representative optical microscope images of the glass substrate in different regions of the anode-side surface after humid aging. As shown in this image, the unpoled region (left side of FIG. 5) is substantially corroded, showing relatively large weathering products scattered in various forms on the surface, and which are known to lead to unwanted light extraction. Meanwhile, the poled region (right side of FIG. 5) is free from any discernible evidence of weathering products, even at this microscopic scale. The images show different representative spots at the same magnification on the samples. Those skilled in the art recognize that “weathering” products are often inhomogeneously distributed when examined at higher magnifications in a microscope, but appear as a more-or-less uniform haze in the ensemble when viewed at macroscopic conditions. There is a slight visible “texture” observed on the glass surface in the microscope images, and that is solely an effect of the gage-block-electrode's surface texture being slightly imprinted onto the glass surface, as described in the art. Briefly stated, when ions migrate and the alkali-depleted surface layer forms, there is a small reduction in volume that leads to a shallow, subtractive imprinting of the topography/texture of the anodic electrode in the glass surface. The poled surface is free of virtually any evidence of weathering corrosion.

According to one or more embodiments, the alkali-depleted surface layer is depleted of all, or substantially all, alkali (e.g., Na⁺) and alkaline-earth (e.g., Mg⁺) to a depth of several hundred nanometers. This leaves behind a surface layer that contains only, or substantially contains only, the network-formers (SiO₂ and Al₂O₃, plus minor amounts of Sn). For the glass substrate used in this Example, the composition of the alkali-depleted surface layer is estimated to be about 93.8% SiO₂ and 6.3% Al₂O₃, as estimated based on subtraction of alkali oxide and alkaline-earth oxide elements from the composition. This alkali-depleted surface layer is expected to be more resistant to corrosion effects that otherwise occurs in untreated glass substrates due to alkali diffusion, particularly in high temperature and/or high humidity environments.

1. A light guide plate, comprising:
a glass substrate including an edge surface and at least two major surfaces defining a thickness and an edge surface configured to receive light from a light source and the glass substrate configured to distribute the light from the light source; wherein the glass substrate comprises:
an alkali-containing bulk; and
an alkali-depleted surface layer, the alkali-depleted surface layer comprising about 0.5 atomic % alkali or less.

2. The light guide plate of claim 1, wherein the alkali-depleted surface layer comprises about 0.5 atomic % alkaline earth or less.

3. The light guide plate of claim 1, wherein the alkali-depleted surface layer comprises greater than about 90 mol % SiO₂ and at least about 5 mol % Al₂O₃.

4. The light guide plate of claim 1, wherein the light guide plate exhibits a transmittance normal to the alkali-depleted surface layer greater than 90% over a wavelength range from 400 nm to 700 nm.

5. The light guide plate of claim 1, further comprising one or more of a light extraction feature (LEF) and a lenticular lens on the alkali-depleted surface layer.

6. The light guide plate of claim 1, wherein the alkali-depleted surface layer reduces formation of weathering products upon aging at 60° C. and 90% relative humidity for 960 hours compared to a light guide plate that does not comprise an alkali-depleted surface layer.

7. The light guide plate of claim 2, wherein the alkali-containing bulk comprises, on a mol % oxide basis:
50-90 mol % SiO₂,
0-20 mol % Al₂O₃,
0-20 mol % B₂O₃, and
0-25 mol % RₓO,
wherein x is 2 and R is chosen from Li, Na, K, Rb, Cs, and combinations thereof, or wherein x is 1 and R is chosen from Zn, Mg, Ca, Sr, Ba, and combinations thereof, and wherein the alkali-containing bulk comprises at least 0.5 mol % of one oxide selected from Li₂O, Na₂O, K₂O and MgO.

8. The light guide plate of claim 7, wherein the alkali-containing bulk comprises at least 3.5 mol % of one oxide selected from Li₂O, Na₂O, K₂O and MgO.

9. The light guide plate of claim 2, wherein the alkali-containing bulk comprises, on a mol % oxide basis:
from about 65.8 mol % to about 78.2 mol % SiO₂;
from about 2.9 mol % to about 12.1 mol % Al₂O₃;
from about 0 mol % to about 11.2 mol % B₂O₃;
from about 0 mol % to about 2 mol % Li₂O;
from about 3.5 mol % to about 13.3 mol % Na₂O;
from about 0 mol % to about 4.8 mol % K₂O;
from about 0 mol % to about 3 mol % ZnO;
from about 0 mol % to about 8.7 mol % MgO;
from about 0 mol % to about 4.2 mol CaO %;
from about 0 mol % to about 6.2 mol % SrO;
from about 0 mol % to about 4.3 mol % BaO; and
from about 0.07 mol % to about 0.11 mol % SnO₂.

10. The light guide plate of claim 9, wherein the alkali-containing bulk comprises an alkali-metal oxide selected from Li₂O, Na₂O, K₂O, Rb₂O and Cs₂O.

11. The light guide plate of claim 10, wherein the alkali-containing bulk comprises at least 3.5 mol % of one oxide selected from Li₂O, Na₂O, K₂O and MgO.

12. A display product comprising:
a light source;
a reflector; and
the light guide plate of claim 1.

13. The display product of claim 12, wherein the light source is a light emitting diode (LED) optically coupled to the edge surface of the glass substrate.

14. A method of manufacturing a light guide plate, the method comprising:
providing a glass substrate comprising at least two major surfaces defining a thickness and an edge surface configured to receive light from a light source and the glass substrate configured to distribute the light from the light source;
contacting at least one of the at least two major surfaces with an electrode; and
subjecting the glass substrate to thermal poling, wherein weathering-based, non-uniformity in brightness in the light guide plate arising from formation of alkali products on the glass substrate is reduced, compared to a glass substrate that has not been subjected to thermal poling.

15. The method of claim 14, wherein the electrode comprises an anode in contact with an anodic surface of the glass substrate and a cathode in contact with a cathodic surface of the glass substrate and wherein thermal poling comprises applying voltage to the glass substrate such that the anode is positively-biased relative to the glass substrate to induce alkali depletion at the anodic surface of the glass substrate.

16. The method of claim 15, wherein the voltage comprises DC voltage or DC-biased AC voltage.

17. The method of claim 15, wherein thermal poling comprises bringing the glass substrate and electrode to a temperature below Tg prior to applying voltage to the glass substrate.

18. The method of claim 14, wherein the thermal poling comprises applying voltage in a range of from about 100 volts to about 10,000 volts to the glass substrate for a during in a range of from about 1 minute to about 6 hours.

19. The method of claim 14, wherein the glass substrate is subjected to thermal poling under vacuum, in an inert gas environment, or a permeable gas environment.

20. The method of claim 14, wherein thermal poling results in an alkali-depleted surface layer, the alkali-depleted surface layer comprising about 0.5 atomic % alkali or less.
